(19) United States
(12) Patent Application Publication
(10) Pub. No.: US 2024/0414993 A1
(43) Pub. Date: Dec. 12, 2024

(54) DISPLAY DEVICE AND MANUFACTURING METHOD THEREOF

(71) Applicant: Samsung Display Co., Ltd., Yongin-si (KR)

(72) Inventors: Sangduk LEE, Yongin-si (KR); Hoikwan LEE, Yongin-si (KR); Eun-Kyung YEON, Yongin-si (KR)

(21) Appl. No.: 18/607,430

(22) Filed: Mar. 16, 2024

(30) Foreign Application Priority Data
Jun. 7, 2023 (KR) 10-2023-0072566

(51) Int. Cl. H10K 59/80

(52) U.S. Cl. CPC H10K 59/8792; H10K 59/871

(57) ABSTRACT

Disclosed is a display device which includes a display module and a window. The window includes a transmission region and a bezel region adjacent to the transmission region, and the window is directly disposed on the display module. The window includes a resin material. The display device includes a light blocking pattern that overlaps the bezel region. An outside surface of the window protrudes further outward compared to an outside surface of the display module, and a front surface of the window includes a curved portion. The curved portion curves toward a rear surface of the window as a distance from the transmission region increases.

### CROSS-REFERENCE TO RELATED APPLICATIONS

This application claims priority to Korean Patent Application No. 10-2023-0072566, filed on Jun. 7, 2023, and all the benefits accruing therefrom under 35 U.S.C. § 119, the content of which in its entirety is herein incorporated by reference.

### BACKGROUND

### Field

Embodiments of the present disclosure described herein relate to a display device and a manufacturing method thereof, and more particularly, relate to a display device including a window.

### Description of the Related Art

A display device, such as, for example, a television, a monitor, a smart phone, a tablet computer, or the like, may provide an image to a user and include a display panel that displays the image. Various display panels, such as, for example, a liquid crystal display panel, an organic light emitting display panel, an electro wetting display panel, an electrophoretic display panel, and the like, are being developed as display panels. Some display devices may include a window for protecting the display panel. In some cases, the window may be attached to the display panel through a lamination process.

### SUMMARY

Embodiments of the present disclosure provide a display device including a light blocking pattern and a window.

Embodiments of the present disclosure provide a method of manufacturing a display device including a light blocking pattern and a window.

According to an embodiment, a display device includes a display module, a window that includes a transmission region and a bezel region adjacent to the transmission region and that is directly disposed on the display module and including a resin material, and a light blocking pattern that overlaps the bezel region. An outside surface of the window protrudes further outward compared to an outside surface of the display module, and a front surface of the window includes a curved portion, and the curved portion curves toward a rear surface of the window as a distance from the transmission region increases.

The window may include a first window that is directly disposed on the display module and that has a first modulus value and a second window that is directly disposed on the first window and that has a second modulus value greater than the first modulus value.

The light blocking pattern may be directly disposed between the first window and the second window.

The window may include a first portion that overlaps the transmission region, where a distance between a front surface and a rear surface of the first portion may be constant. The window may include a second portion that overlaps the bezel region, where a distance between a front surface and a rear surface of the second portion may decrease as the distance from the first portion increases.

The light blocking pattern may be directly disposed on the rear surface of the window.

The window may be spaced apart from the outside surface of the display module.

The light blocking pattern may have a thickness of 5 micrometers or less.

A width of the window in a first direction may be greater than a width of the display module in the first direction.

According to an embodiment, a method for manufacturing a display device includes providing a first resin material on a first jig including a seating surface, wherein at least a portion of the seating surface between an inner surface and a lower surface of the seating surface is defined to be curved, forming a first window by curing the first resin material, the first window including a transmission region and a bezel region adjacent to the transmission region, forming a light blocking pattern that is directly disposed on the first window and that overlaps the bezel region, providing a second resin material on the first window, directly placing a display module on the second resin material, and forming a second window by curing the second resin material.

The directly placing of the display module on the second resin material may include placing the display module on a second jig having a shape corresponding to the first jig and directly placing the display module on the second resin material by pressing the first jig and the second jig by moving at least one of the first jig and the second jig.

The second jig may be coupled with an attraction module and may attract the display module based on an attraction force generated by the attraction module, and the second jig may fix the display module to one surface of the second jig based on the attraction force generated by the attraction module.

The second jig may include a support portion on which the display module is seated and a protruding portion that protrudes from the support portion, and a width of the protruding portion may correspond to a distance between an outside surface of the display module and an outside surface of the second window.

A height of the protruding portion may be smaller than a thickness of the display module.

At least one of the first jig and the second jig may include a material which may transmit UV light.

A front surface of the first window may include a curved portion, and the curved portion curves toward a rear surface as a distance from the transmission region increases, and the seating surface of the first jig may substantially correspond to the curved portion.

According to an embodiment, a method for manufacturing a display device includes providing a resin material on a first jig including a seating surface, wherein at least a portion of the seating surface between an inner surface and a lower surface of the seating surface is defined to be curved, forming a preliminary window by pre-curing the resin material, the preliminary window including a transmission region and a bezel region adjacent to the transmission region, forming a light blocking pattern that is directly disposed on the preliminary window and that overlaps the bezel region, directly placing a display module on the preliminary window, and forming a window by curing the preliminary window.

The directly placing of the display module on the preliminary window may include placing the display module on a second jig having a shape corresponding to the first jig and directly placing the display module on the preliminary window by pressing the first jig and the second jig by moving at least one of the first jig and the second jig.

The second jig may include a protruding portion that protrudes toward the first jig, and a thickness of the protruding portion in a first direction may correspond to a distance between an outside surface of the display module and an outside surface of the window.

At least one of the first jig and the second jig may include a material which transmits UV light.

A front surface of the window may include a curved portion, and the curved portion curves toward a rear surface as a distance from the transmission region increases, and the seating surface of the first jig may substantially correspond to the curved portion.

### BRIEF DESCRIPTION OF THE DRAWINGS

The above and other objects and features of the present disclosure will become apparent by describing in detail embodiments thereof with reference to the accompanying drawings.

FIG. 1 is a perspective view of a display device according to an embodiment of the present disclosure.

FIG. 2 is an exploded perspective view of the display device according to an embodiment of the present disclosure.

FIG. 3 is a sectional view of a display module according to an embodiment of the present disclosure.

FIG. 4 is a plan view of a display panel according to an embodiment of the present disclosure.

FIG. 5 is a sectional view taken along line I-I′ of FIG. 2 according to an embodiment of the present disclosure.

FIG. 6 is an enlarged sectional view illustrating region AA of FIG. 5 according to an embodiment of the present disclosure.

FIG. 7 is a sectional view taken along line I-I′ of FIG. 2 according to an embodiment of the present disclosure.

FIG. 8 is an enlarged sectional view illustrating region BB of FIG. 7 according to an embodiment of the present disclosure.

FIGS. 9A to 9H are sectional views illustrating a manufacturing method of the display device according to an embodiment of the present disclosure.

FIGS. 10A to 10F are sectional views illustrating a manufacturing method of the display device according to an embodiment of the present disclosure.

### DETAILED DESCRIPTION

In the present specification, when a component (or, an area, a layer, a part, etc.) is referred to as being “on”, “connected to” or “coupled to” another component, the description means that the component may be directly on, connected to, or coupled to the other component or with a third component present between the component and the other component.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified. The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

In addition, terms such as, for example, “below”, “under”, “above”, and “over” are used to describe a relationship of components illustrated in the drawings. The terms are relative concepts and are described based on directions illustrated in the drawing.

It should be understood that terms such as, for example, “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

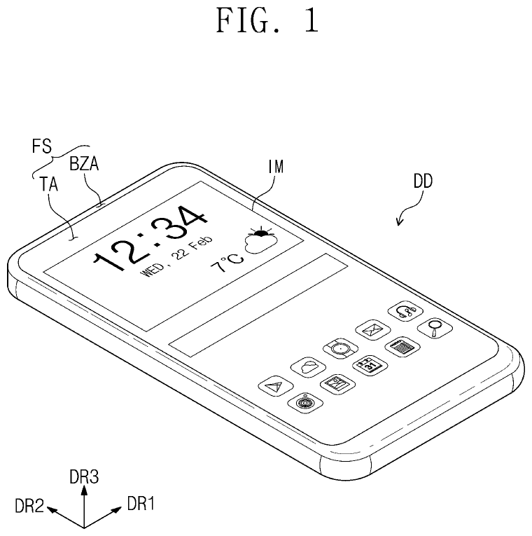

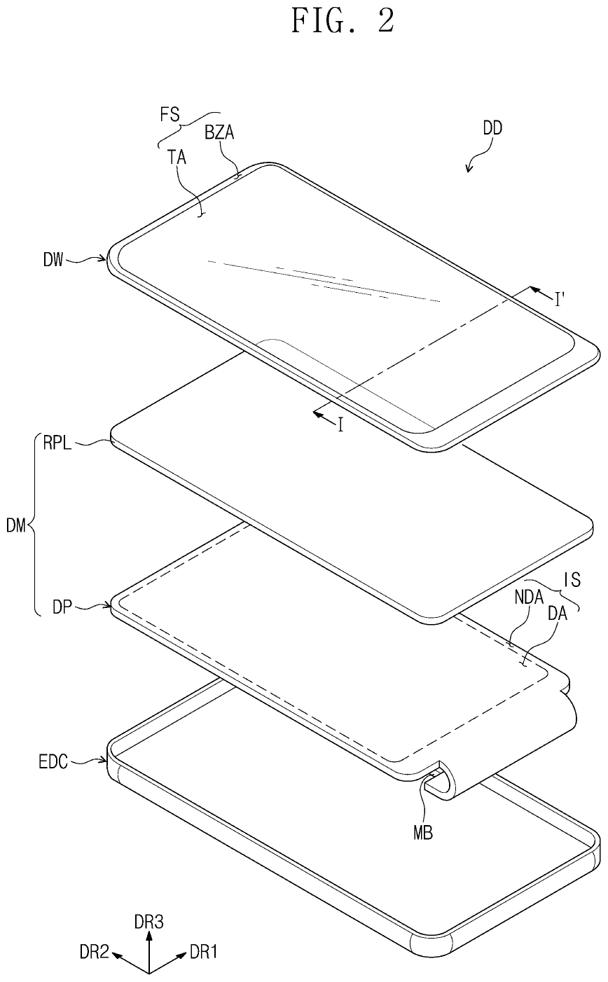

FIG. 1 is a perspective view of a display device DD according to an embodiment of the present disclosure, and FIG. 2 is an exploded perspective view of the display device DD according to an embodiment of the present disclosure.

Referring to FIGS. 1 and 2, the display device DD may be activated based on an electrical signal and may display an image. For example, the display device DD may be included in a small-sized or and medium-sized device such as, for example, a monitor, a mobile phone, a tablet computer, a computer, a car navigation unit, a game machine, or the like, as well as a large device such as, for example, a television, a billboard, or the like. The embodiments of the display device DD are illustrative, and the display device DD is not limited to any one embodiment as long as it does not depart from the spirit and scope of the present disclosure. It will be understood that other embodiments of the display device DD may be used without departing from the spirit and scope of the present disclosure. In this embodiment, a mobile phone is illustrated as an example of the display device DD.

Referring to FIG. 1, on a plane, the display device DD may have a rounded quadrangular shape with short sides extending in a first direction DR1 and long sides extending in a second direction DR2 crossing the first direction DR1. However, without being limited thereto, the display device DD may have various shapes such as, for example, a rectangular shape, a square shape, a circular shape, a polygonal shape, an irregular shape, and the like on the plane.

The display device DD of an embodiment may be a flexible display device. The term “flexible” used herein may mean a property of being bent or bendable and may include everything from a structure that is fully folded to a structure that can be bent to a level of several nanometers. For example, the flexible display device DD may include a curved display device, a foldable display device, or a slidable or rollable display device. However, without being limited thereto, the display device DD may be a rigid display device.

The display device DD may display an image IM in a third direction DR3 on a display surface parallel to the first direction DR1 and the second direction DR2. The image IM provided by the display device DD may include a still image as well as a dynamic image. In FIG. 1, a clock window and icons are illustrated as examples of the image IM. The display surface on which the image IM is displayed may correspond to a front surface of the display device DD and may correspond to a front surface FS of a window DW (refer to FIG. 2). The planar display surface is illustrated as an example in FIG. 1. However, without being limited thereto, the display surface of the display device DD may include a curved surface bent from at least one side of a flat surface.

Front surfaces (or, upper surfaces) and rear surfaces (or, lower surfaces) of members constituting the display device DD may be opposite each other in the third direction DR3, and the normal directions of the front surfaces and the rear surfaces may be substantially parallel to the third direction DR3. The separation distances between the front surfaces and the rear surfaces defined in the third direction DR3 may correspond to the thicknesses of the members (or, units). The expression “from above a plane” used herein may mean that a corresponding component or feature is viewed in the third direction DR3. The expression “on a section” used herein may mean that a corresponding component or feature is viewed in the first direction DR1 or the second direction DR2. The directions indicated by the first to third directions DR1, DR2, and DR3 may be relative concepts and may be changed to different directions.

Referring to FIG. 2, the display device DD may include the window DW, a display module DM, and a case EDC. The window DW may be coupled with the case EDC to define the exterior of the display device DD.

The window DW may be disposed on the display module DM. The window DW may have a shape corresponding to the shape of a display panel DP. The window DW may cover the entire outside of the display module DM and may protect the display module DM from external impacts and scratches.

The window DW may include an optically clear insulating material. For example, the window DW may include a resin material. The window DW may be a single-layer structure or a multi-layer structure. The window DW may further include functional layers, such as, for example, an anti-fingerprint layer, a phase control layer, and a hard coating layer, which are disposed on an optically clear layer. In the display device DD including the window DW according to some embodiments of the present disclosure, methods described herein may include manufacturing the display device, while omitting a lamination process. Accordingly, embodiments supported by the present disclosure provide a display device manufacturing process having reduced complexity (e.g., a simplified manufacturing process) and reduced costs.

The front surface FS of the window DW may include a transmission region TA and a bezel region BZA. The transmission region TA of the window DW may be an optically clear region. The window DM may transmit the image IM provided by the display panel DP through the transmission region TA, and a user may visually recognize the corresponding image IM.

The bezel region BZA of the window DW may overlap a light blocking pattern BM (refer to FIG. 5) that will be described below. The light blocking pattern BM (refer to FIG. 5) may be a rigid substrate including a material having a predetermined color. The bezel region BZA of the window DW may prevent a component of the display panel DP disposed to overlap the bezel region BZA from being visible from the outside. The term “the outside” used herein may refer to outside of or external to the display device DD.

The bezel region BZA may be adjacent to the transmission region TA. The shape of the transmission region TA may be substantially defined by the bezel region BZA. For example, the bezel region BZA may be disposed around the transmission region TA and may surround the transmission region TA. However, the example is illustrative, and the bezel region BZA may be disposed adjacent to a single side of the transmission region TA, or the bezel region BZA may be omitted. Alternatively, the bezel region BZA may be disposed on a side surface of the display device DD, additional or alternative to being disposed on the front surface of the display device DD.

The display module DM may include an optical layer RPL and the display panel DP. However, without being limited to the optical layer RPL and the display panel DP, the display module DM may further include general-purpose components.

The optical layer RPL may be disposed between the display panel DP and the window DW. The optical layer RPL may lower the reflectance of light incident from the outside. The optical layer RPL may include a phase retarder and/or a polarizer. The optical layer RPL may include at least a polarizer film. In this example case, the optical layer RPL may be attached to the display panel DP through an adhesive layer. However, the example is illustrative, and the present disclosure is not limited thereto. For example, the optical layer RPL may include color filters.

The display panel DP may be disposed between the window DW and the case EDC. The display panel DP may display an image in response to an electrical signal. The display panel DP according to an embodiment may be an emissive display panel, but is not particularly limited thereto. For example, the display panel DP may be an organic light emitting display panel, an inorganic light emitting display panel, an organic-inorganic light emitting display panel, or a quantum-dot light emitting display panel. An emissive layer of the organic light emitting display panel may include an organic light emitting material, and an emissive layer of the inorganic light emitting display panel may include an inorganic light emitting material. An emissive layer of the organic-inorganic light emitting display panel may include an organic-inorganic light emitting material. An emissive layer of the quantum-dot light emitting display panel may include quantum dots and quantum rods.

The image IM provided by the display device DD may be displayed on a front surface IS of the display panel DP. The front surface IS of the display panel DP may include a display region DA and a non-display region NDA. The display region DA may be a region that is activated based on an electrical signal and that displays an image. According to an embodiment, the display region DA of the display panel DP may correspond to the transmission region TA of the window DW. The expression “one region/portion corresponds to another region/portion” used herein means that “the regions/portions overlap each other”, but is not limited to the regions/portions as having the same area and/or the same shape.

The non-display region NDA may be adjacent to the outside of the display region DA. For example, the non-display region NDA may surround the display region DA. However, without being limited thereto, the non-display region NDA may be defined in various shapes.

The non-display region NDA may be a region in which a drive circuit or drive wiring for driving elements disposed in the display region DA, various types of signal lines for providing electrical signals, and pads are disposed. The non-display region NDA of the display panel DP may correspond to the bezel region BZA of the window DW. The bezel region BZA may prevent components of the display panel DP disposed in the non-display region NDA from being visible from the outside.

The display device DD may include a circuit board MB connected to the display panel DP. The circuit board MB may be connected to one end of the display panel DP that extends in the first direction DR1. The circuit board MB may generate an electrical signal to be provided to the display panel DP. For example, the circuit board MB may include a timing controller that generates a signal to be provided to a driver of the display panel DP in response to control signals received from the outside.

At least a portion of the non-display region NDA of the display panel DP may be bent. A portion of the display panel DP to which the circuit board MB is connected may be bent such that the circuit board MB faces toward a rear surface of the display panel DP. The circuit board MB may be disposed and assembled such that the circuit board MB overlaps the rear surface of the display panel DP on the plane. However, without being limited thereto, the display panel DP and the circuit board MB may be connected through a flexible circuit board that is connected to one end of the display panel DP and one end of the circuit board MB.

The case EDC may provide an inner space in which components of the display device DD are accommodated. The case EDC may be disposed under the display panel DP and may accommodate the display panel DP. The case EDC may include glass, plastic, or a metallic material that has a relatively high rigidity. The case EDC may protect the display panel DP by absorbing an impact applied from the outside or preventing infiltration of foreign matter/moisture into the display panel DP.

In some embodiments, the display device DD may further include an electronic module including various functional modules for operating the display panel DP and a power supply module for supplying power to the display device DD (e.g., power required for the display device DD). For example, the display device DD may include a camera module as an example of the electronic module.

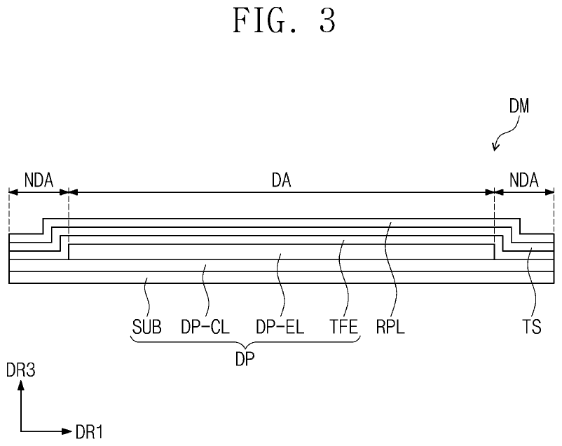

FIG. 3 is a sectional view of the display module DM according to an embodiment of the present disclosure.

Referring to FIG. 3, the display module DM may include the display panel DP, an input sensing layer TS, and the optical layer RPL. The display panel DP may display an image based on an electrical signal, and the input sensing layer TS may sense an external input applied from the outside. The external input may be provided in various forms.

The display panel DP according to an embodiment of the present disclosure may be an emissive display panel and is not particularly limited. For example, the display panel DP may be an organic light emitting display panel, an inorganic light emitting display panel, or a quantum-dot light emitting display panel. An emissive layer of the organic light emitting display panel may include an organic light emitting material, and an emissive layer of the inorganic light emitting display panel may include an inorganic light emitting material. An emissive layer of the quantum-dot light emitting display panel may include quantum dots and quantum rods. Hereinafter, for purposes of example in the embodiments described herein, the display panel DP is an organic light emitting display panel.

The display panel DP may include a base layer SUB, a display element layer DP-EL, a circuit layer DP-CL, and an encapsulation layer TFE. The display panel DP according to the present disclosure may be a flexible display panel. However, the present disclosure is not limited thereto. For example, the display panel DP may be a foldable display panel that is foldable or folded about a folding axis, or the display panel DP may be a rigid display panel.

The base layer SUB may include a synthetic resin layer. The synthetic resin layer may be a polyimide-based resin layer, and the material thereof is not particularly limited. In some embodiments, the base layer SUB may include a glass substrate, a metal substrate, or an organic/inorganic composite substrate.

The circuit layer DP-CL is disposed between the base layer SUB and the display element layer DP-EL. The circuit layer DP-CL includes at least one insulating layer and a circuit element. Hereinafter, the insulating layer included in the circuit layer DP-CL is referred to as the intermediate insulating layer. The intermediate insulating layer includes at least one intermediate inorganic layer and at least one intermediate organic layer. The circuit element may include a pixel drive circuit included in each of a plurality of pixels for displaying an image. The circuit layer DP-CL may further include signal lines connected to the pixel drive circuit and/or a sensor drive circuit.

The display element layer DP-EL may include a light emitting element included in each of the pixels. A plurality of light emitting elements may be provided. For example, the display element layer DP-EL may include a plurality of light emitting elements. The plurality of light emitting elements may correspond to a plurality of emissive regions. For example, the plurality of emissive regions may include a red light emitting region, a green light emitting region, and a blue light emitting region.

The encapsulation layer TFE may be disposed on the display element layer DP-EL and may seal the display element layer DP-EL. The encapsulation layer TFE may include at least one organic layer and at least one inorganic layer. The inorganic layer may include an inorganic material and may protect the display element layer DP-EL from moisture/oxygen. The inorganic layer may include a silicon nitride layer, a silicon oxy-nitride layer, a silicon oxide layer, a titanium oxide layer, or an aluminum oxide layer, but is not particularly limited thereto. The organic layer may include an organic material and may protect the display element layer DP-EL from foreign matter such as, for example, dust particles.

The input sensing layer TS may be formed on the display panel DP. The input sensing layer TS may be directly disposed on the encapsulation layer TFE. According to an embodiment of the present disclosure, the input sensing layer TS may be formed on the display panel DP by a continuous process. That is, in an example in which the input sensing layer TS is directly disposed on the display panel DP and formed on the display panel DP by a continuous process, the display device DD may be implemented without disposing an adhesive film between the input sensing layer TS and the encapsulation layer TFE. Alternatively, an adhesive film may be disposed between the input sensing layer TS and the display panel DP. In this example case, the input sensing layer TS may not be manufactured together with the display panel DP by a continuous process and may be manufactured separately from the display panel DP and then fixed to an upper surface of the display panel DP by the adhesive film.

The input sensing layer TS may sense an external input (e.g., a touch of the user), may change the sensed external input to a predetermined input signal, and may provide the input signal to the display panel DP. The input sensing layer TS may include a plurality of sensing electrodes for sensing the external input. The sensing electrodes may sense external inputs of a capacitive type. The display panel DP may receive the input signal from the input sensing layer TS and may generate an image corresponding to the input signal.

The optical layer RPL may be disposed on the input sensing layer TS. The optical layer RPL may be an anti-reflective layer that lowers the reflectance of external light incident from the outside. The optical layer RPL may be a layer that selectively transmits light emitted from the display panel DP. The optical layer RPL may be implemented without a polarization layer (e.g., in some embodiments, the optical layer RPL does not include a polarization layer). Accordingly, light incident to the display panel DP and the input sensing layer TS through the optical layer RPL may be unpolarized light. The display panel DP and the input sensing layer TS may receive unpolarized light from the optical layer RPL. However, the present disclosure is not limited thereto. The optical layer RPL may be a color filter layer including separate filter units and a black matrix. Although not illustrated, the filter units may include a red filter unit, a green filter unit, and a blue filter unit. The red filter unit, the green filter unit, and the blue filter unit may be units located to correspond to a red light emitting region, a green light emitting region, and a blue light emitting region, respectively.

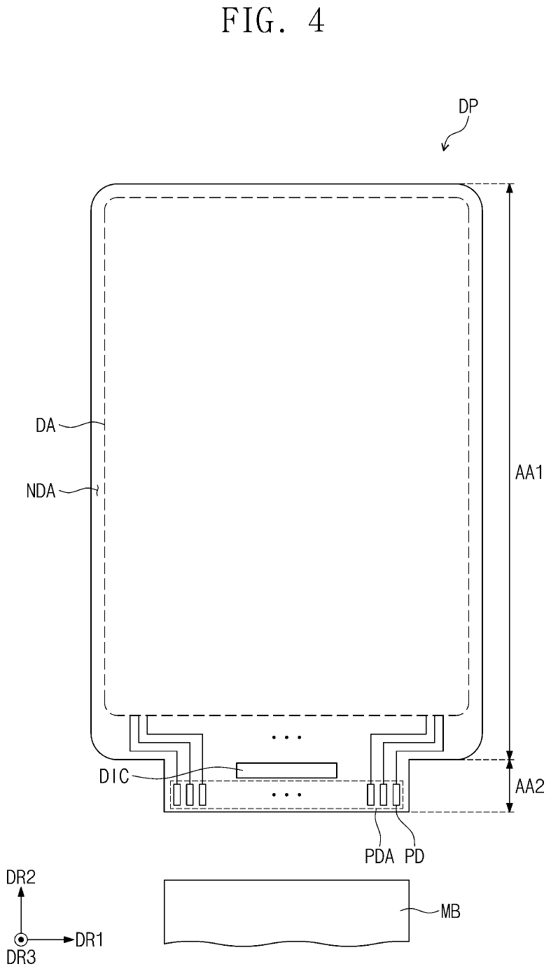

FIG. 4 is a plan view of the display panel DP according to an embodiment of the present disclosure.

Referring to FIG. 4, the display panel DP may include a first region AA1 and a second region AA2. The first region AA1 may be a display part of the display panel DP, and the second region AA2 may be a bendable part of the display panel DP.

The first region AA1 may include a display region DA and a non-display region NDA adjacent to the display region DA. The second region AA2 may include the non-display region NDA. The second region AA2 may extend from the first region AA1. For example, the second region AA2 may extend from the first region AA1 in a direction opposite to the second direction DR2.

The second region AA2 may include a pad region PDA. A plurality of pads PD may be disposed in the pad region PDA. The plurality of pads PD may be arranged in the first direction DR1 such that the plurality of pads PD are spaced apart from each other. In some embodiments, a driver IC DIC may be disposed in the second region AA2. The plurality of pads PD may be electrically connected to the driver IC DIC and a plurality of circuit lines extending from the first region AA1. Some of the plurality of pads PD may be pads for connecting the circuit board MB to the display panel DP. The plurality of pads PD may be connected to corresponding pixels through the plurality of circuit lines extending from the first region AA1. The second region AA2, to which the circuit board MB is connected, may be bent to face toward a rear surface of the first region AA1.

FIG. 5 is a sectional view taken along line I-I′ of FIG. 2 according to an embodiment of the present disclosure.

Referring to FIG. 5, the display device DD may include a protective panel CP, the display module DM, the light blocking pattern BM, first and second adhesive layers AM1 and AM2, and the window DW. The detailed configuration of the display module DM has been described with reference to FIG. 3. Therefore, identical components are assigned with identical reference identifiers, and repeated descriptions of like elements will be omitted for brevity.

The first adhesive layer AM1 and the second adhesive layer AM2, which will be described below, may be pressure sensitive adhesive (PSA) films, optically clear adhesive (OCA) films, or optically clear resins (OCRs). In some embodiments, the first adhesive layer AM1 and the second adhesive layer AM2 may each include a photo-curable adhesive material or a heat-curable adhesive material, and the materials thereof are not particularly limited. In some embodiments, one or more portions of the first adhesive layer AM1 and/or the second adhesive layer AM2 may be omitted.

The protective panel CP may be disposed on a lower surface of the display module DM. The protective panel CP may protect the display panel DP from an impact transmitted from below the display panel DP. The protective panel CP may be attached to the lower surface of the display module DM by the second adhesive layer AM2. Although the protective panel CP is illustrated as a single layer in the example of FIG. 5, in some embodiments, the protective panel CP may have a multi-layer structure including a barrier layer and a cushion layer.

The barrier layer of the protective panel CP may be of a color with a low light transmittance and thus may prevent components under the barrier layer from being visible. The cushion layer of the protective panel CP may be disposed on the barrier layer and may absorb an impact transmitted from below the display panel DP. The cushion layer of the protective panel CP may be formed of a highly elastic material such as, for example, a foam sheet having a plurality of openings formed therein.

The display module DM may be disposed between the protective panel CP and the window DW. The display module DM may display an image based on an electrical signal and may sense an external input applied from the outside. The display module DM may include the display panel DP, the input sensing layer TS, the first adhesive layer AM1, and the optical layer RPL. However, the configuration of the display module DM is not limited thereto, and general-purpose components may be additionally included in the display module DM. In some embodiments, the stacking sequence of the display module DM may vary without being limited to the example illustrated in FIG. 5.

The window DW may be directly disposed on the display module DM. The expression “directly disposed” used herein means that components make direct contact with each other without a separate adhesive layer or film between the components. That is, in an example in which window DW is directly disposed on the display module DM, the display device DD may be implemented without disposing a member for adhesion, such as, for example, a separate adhesive layer or film, between the window DW and the display module DM. Embodiments of the present disclosure may include bringing a lower surface of the window DW and an upper surface of the display module DM into direct contact with each other, example aspects of which are later described herein.

The window DW may be formed by applying a resin material such as, for example, a resin and curing the resin material. When the window DW is directly disposed on the display module DM as described herein, a separate lamination process for adhesion may be omitted. Accordingly, a manufacturing process of the display device DD may be simplified, and costs may be reduced.

An outside surface of the window DW may protrude further outward compared to an outside surface of the display module DM. The outside surface of the window DW may be a surface furthest from the center of the window DW, and the outside surface of the display module DM may be a surface furthest from the center of the display module DM. Because the outside surface of the window DW protrudes further outward compared to the outside surface of the display module DM, the light blocking pattern BM disposed on a first window LDW may cover the outside of the display module DM. Accordingly, for example, the light blocking pattern BM may prevent a component outside the display module DM from being visible from the outside. For example, the light blocking pattern BM may cover the bent portion of the display panel DP of FIG. 2 such that the light blocking pattern BM prevents the bent portion from being visible from the outside.

The distance T1 by which a left side surface of the window DW of FIG. 5 protrudes further outward compared to a left side surface of the display module DM may be equal to the distance T2 by which a right side surface of the window DW protrudes further outward compared to a right side surface of the display module DM. The width of the window DW in the first direction DR1 may be greater than the width of the display module DM in the first direction DR1.

The window DW may be spaced apart from the outside surface of the display module DM. That is, for example, the window DW may not make contact with the outside surface of the display module DM. The window DW may extend in the first direction DR1. In some embodiments, the window DW may not extend in the third direction DR3 crossing the first direction DR1. For example, the window DW may have a thickness in the third direction DR3, and a width and a length of the window DW may be defined in the first direction DR1 and the second direction DR2.

The front surface of the window DW may include a curved portion that is curved toward the rear surface as the distance from the transmission region TA increases. For example, the curved portion may begin at the front surface of the window DW, at a point located a first distance from the transmission region TA, and the curved portion may end at a point located a second distance (e.g., a farther distance) from the transmission region TA. In some embodiments, a left curved portion and a right curved portion of the window DW may have the same curvature. In some other embodiments, the curvature of the left curved portion and the curvature of the right curved portion of the window DW may differ from each other.

The window DW may include the first window LDW and a second window HDW. The first window LDW may be directly disposed on the display module DM. In an example in which first window LDW is directly disposed on the display module DM, the display device DD may be implemented without disposing a member for adhesion, such as, for example, a separate adhesive or a separate adhesive film, between the first window LDW and the display module DM. A lower surface of the first window LDW may make contact with the upper surface of the display module DM. The first window LDW may be disposed between the display module DM and the second window HDW. The first window LDW may have a first modulus value smaller than a second modulus value of the second window HDW. The first window LDW may have a relatively small modulus value, and the first window LDW may support alleviating an external impact applied to the display module DM. The term “modulus” may refer to a modulus of elasticity (also known as elastic modulus), that is, the measurement of an elasticity of a material. The elastic modulus quantifies the resistance of a material to non-permanent, or elastic, deformation.

The second window HDW may be directly disposed on the first window LDW. In an example in which the second window HDW is directly disposed on the first window LDW, the display device DD may be implemented without disposing a member for adhesion, such as, for example, a separate adhesive or a separate adhesive film, between the second window HDW and the first window LDW. A lower surface of the second window HDW may make contact with an upper surface of the first window LDW. The second window HDW may be disposed on the top of the display device DD and may constitute the front surface FS (refer to FIG. 2) of the window DW. The second window HDW may have the second modulus value greater than the first modulus value of the first window LDW. The second window HDW may have a relatively large modulus value, and the second window HDW may block an external impact applied to the display module DM.

The light blocking pattern BM may be directly disposed between the first window LDW and the second window HDW. The light blocking pattern BM may overlap the bezel region BZA. The area occupied by the light blocking pattern BM on the plane may correspond to the bezel region BZA. The light blocking pattern BM may be a rigid substrate including a material having a predetermined color. The light blocking pattern BM may include a light blocking material and may prevent a component disposed under the light blocking pattern BM from being visible from the outside. The light blocking material may be a black resin through which light does not transmit. In some alternative embodiments, the light blocking pattern BM may partially overlap the bezel region BZA, and the area occupied by the light blocking pattern BM on the plane may correspond to an overlapping portion of the bezel region BZA.

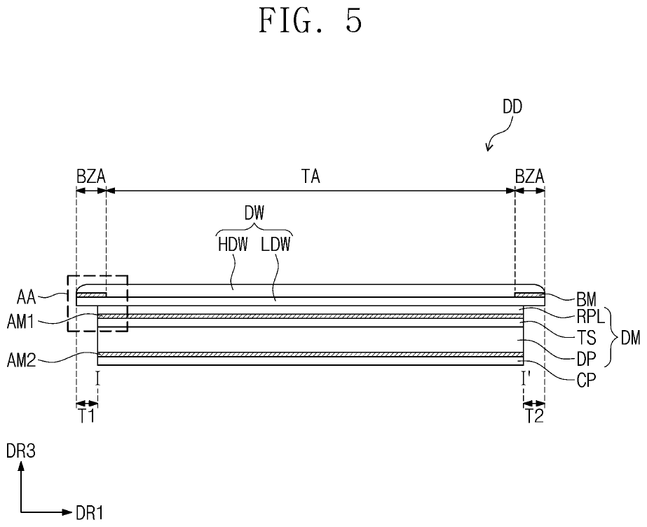

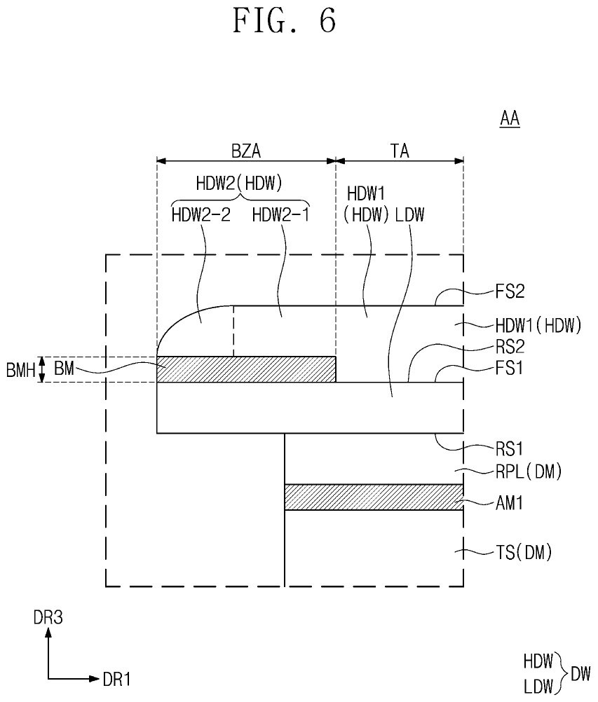

FIG. 6 is an enlarged sectional view illustrating region AA of FIG. 5 according to an embodiment of the present disclosure. Components identical to the components described with reference to FIG. 5 are assigned with identical reference identifiers, and repeated descriptions of like elements will be omitted for brevity.

Referring to FIG. 6, an outside surface of the first window LDW may protrude further outward in a direction opposite to the first direction DR1 compared to the outside surface of the display module DM. The thickness BMH of the light blocking pattern BM may range from 3 micrometers to 5 micrometers. Accordingly, for example, aspects of the light blocking pattern BM described herein may provide improved performance compared to implementations in which the thickness BMH of the light blocking pattern BM is less than 3 micrometers, where the light blocking pattern BM may be excessively thin and therefore may fail to block light. Aspects of the light blocking pattern BM described herein may provide improved performance compared to implementations in which the thickness BMH of the light blocking pattern BM exceeds 5 micrometers, for which there may be difficulties in a manufacturing process. Description thereabout will be given in the description herein of the manufacturing process. In some embodiments, the light blocking pattern BM may have a thickness of about 4 micrometers. The thickness BMH of the light blocking pattern BM as described herein may support effective light blocking capabilities while reducing manufacturing complexity. In some embodiments, the thickness BMH of the light blocking pattern BM may range from about 3 micrometers to about 5 micrometers.

A front surface FS2 of the window DW may include a curved portion and a flat portion. The curved portion may be curved toward the first window LDW. In the curved portion, a minimum distance between the front surface FS2 and a rear surface RS1 of the window DW may decrease as the distance from the transmission region TA increases. For example, the curved portion may begin at the front surface FS2 of the window DW, at a point (indicated by dotted lines at FIG. 6) located a first distance from the transmission region TA, and the curved portion may end at the light blocking pattern BM, at a point located a second distance (e.g., a farther distance) from the transmission region TA. In the flat portion, the distance between the front surface FS2 and the rear surface RS1 of the window DW may be constant. The curved portion may correspond to a front surface of a portionHDW2-2 of the second window HDW. The flat portion may correspond to a front surface of a portionHDW2-1 of the second window HDW and a front surface of a first portion HDW1 of the second window HDW.

The thickness of the first window LDW in the third direction DR3 may be constant. A minimum distance between a front surface FS1 of the first window LDW and a rear surface RS1 of the first window LDW may be constant. The front surface FS1 of the first window LDW may be flat.

A rear surface RS2 of the second window HDW may make contact with the front surface FS1 of the first window LDW. The front surface FS2 of the second window HDW may include a flat portion and a curved portion. The curved portion is curved toward the first window LDW as the distance from the transmission region TA increases. For example, the distance between the front surface FS2 of the second window HDW and the rear surface RS2 of the second window HDW (and accordingly, the distance between the front surface FS2 of the second window HDW and the front surface FS1 of the first window LDW) may decrease, in a direction away from the transmission region TA.

The second window HDW may include the first portion HDW1 overlapping the transmission region TA and a second portion HDW2 overlapping the bezel region BZA. The first portion HDW1 may have the flat portion of the front surface FS2. In the first portion HDW1, a minimum distance between the rear surface RS2 and the front surface FS2 may be constant.

The second portion HDW2 may be directly disposed on the light blocking pattern BM. The second portion HDW2 may include the portion HDW2-1 having a flat portion of the front surface FS2 and the portion HDW2-2 (or, the curved portion) having a curved portion of the front surface FS2. In the portion HDW2-2, a minimum distance in the third direction DR3 between the front surface FS2 and the rear surface RS2 may decrease as the distance from the transmission region TA increases.

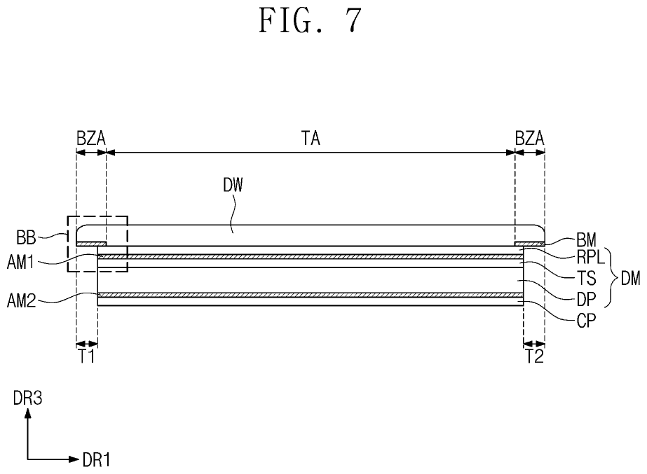

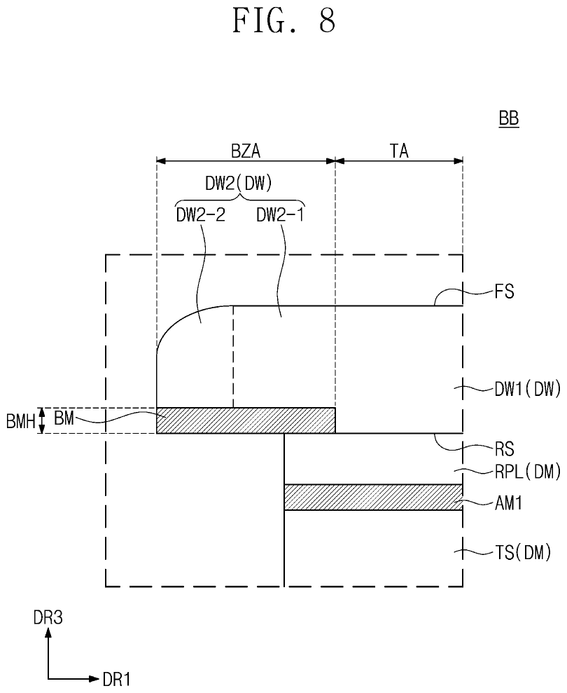

FIG. 7 is a sectional view taken along line I-I′ of FIG. 2 according to an embodiment of the present disclosure, and FIG. 8 is an enlarged sectional view illustrating region BB of FIG. 7 according to an embodiment of the present disclosure. Components identical to the components described with reference to FIGS. 5 and 6 are assigned with identical reference identifiers, and repeated descriptions of like elements will be omitted for brevity.

Referring to FIG. 7, the window DW may be formed to be a single layer. The window DW may be formed by applying and curing the same resin material. The window DW may be directly disposed on the display module DM. The light blocking pattern BM may be directly disposed on the rear surface of the window DW. In the illustrated example, the light blocking pattern BM is directly disposed on rear surfaces of the window DW.

Referring to FIG. 8, a portion of the light blocking pattern BM may be directly disposed on the display module DM. The portion of the light blocking pattern BM may make contact with the upper surface of the display module DM. As described herein with reference to FIG. 6, the thickness BMH of the light blocking pattern BM may range from 3 micrometers to 5 micrometers.

The window HDW may include a first portion DW1 overlapping the transmission region TA and a second portion DW2 overlapping the bezel region BZA. The thickness of the first portion DW1 in the third direction DR3 may be constant. The distance between a front surface FS and a rear surface RS of the first portion DW1 may be constant. The second portion DW2 may include a portion DW2-1 and a portion DW2-2. The distance between a rear surface RS and a front surface FS of the portion DW2-1 may be constant. The distance between a front surface FS and a rear surface RS of the portion DW2-2 may decrease as the distance from the first portion DW1 increases. For example, the distance between the front surface FS and the rear surface RS of the portion DW2-2 may decrease (and accordingly, the distance between the front surface FS of the portion DW2-2 and a front portion of the light blocking pattern BM may decrease), in a direction away from the first portion DW1.

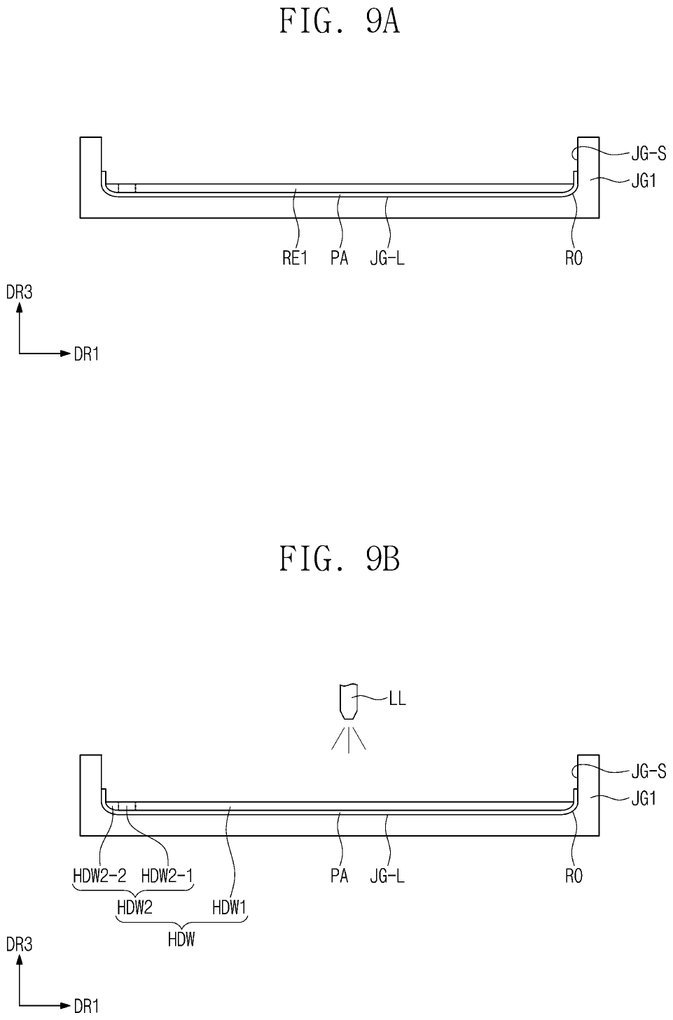

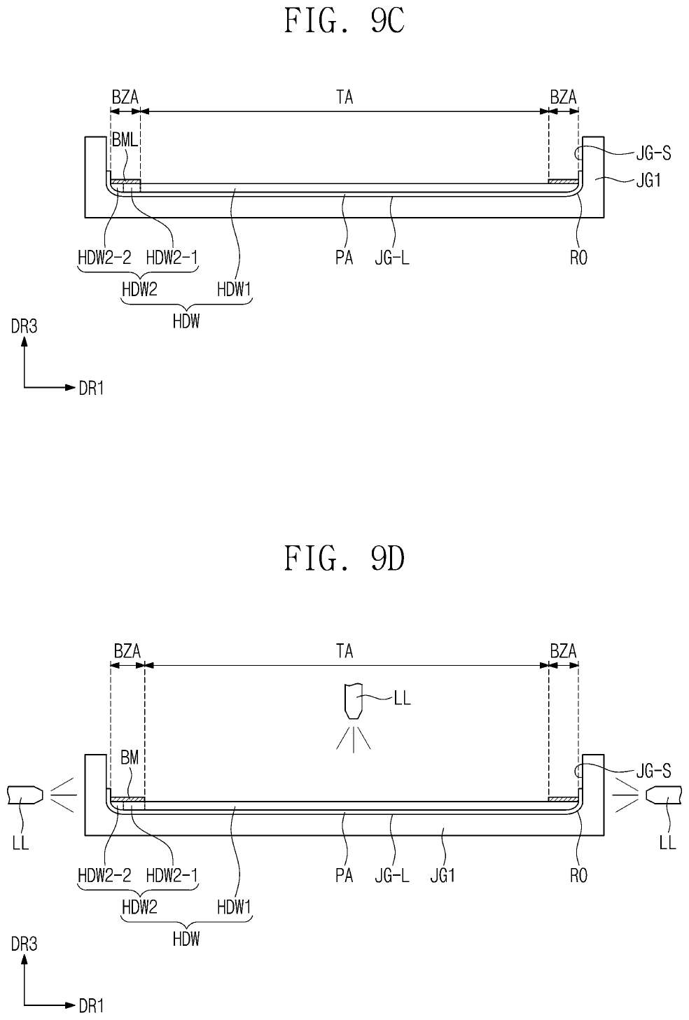

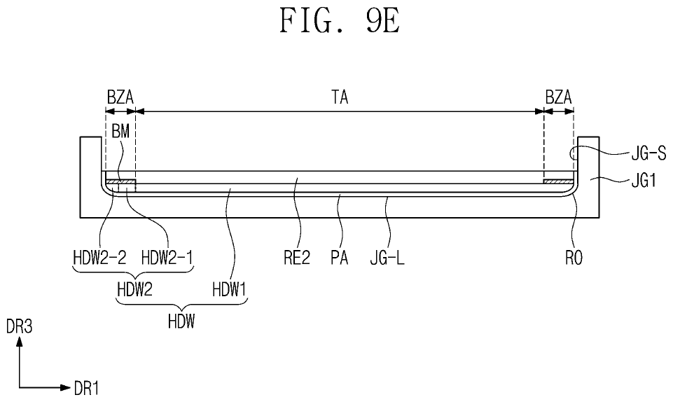

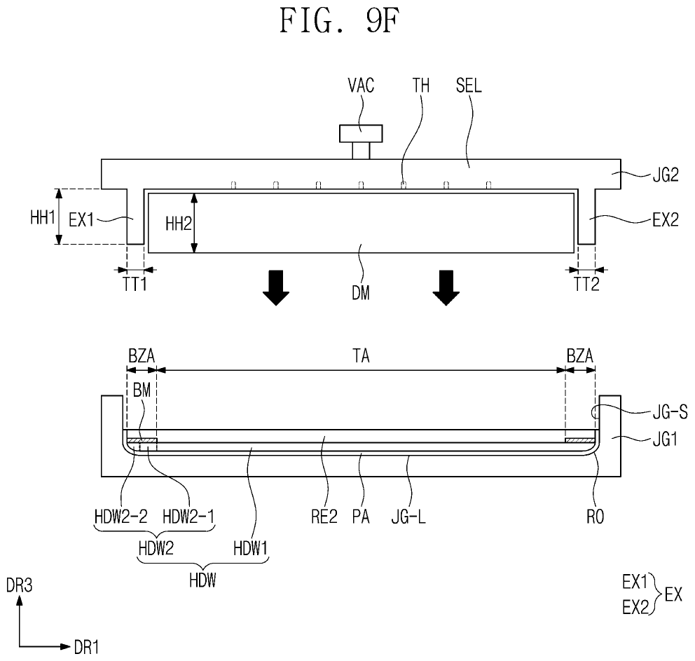

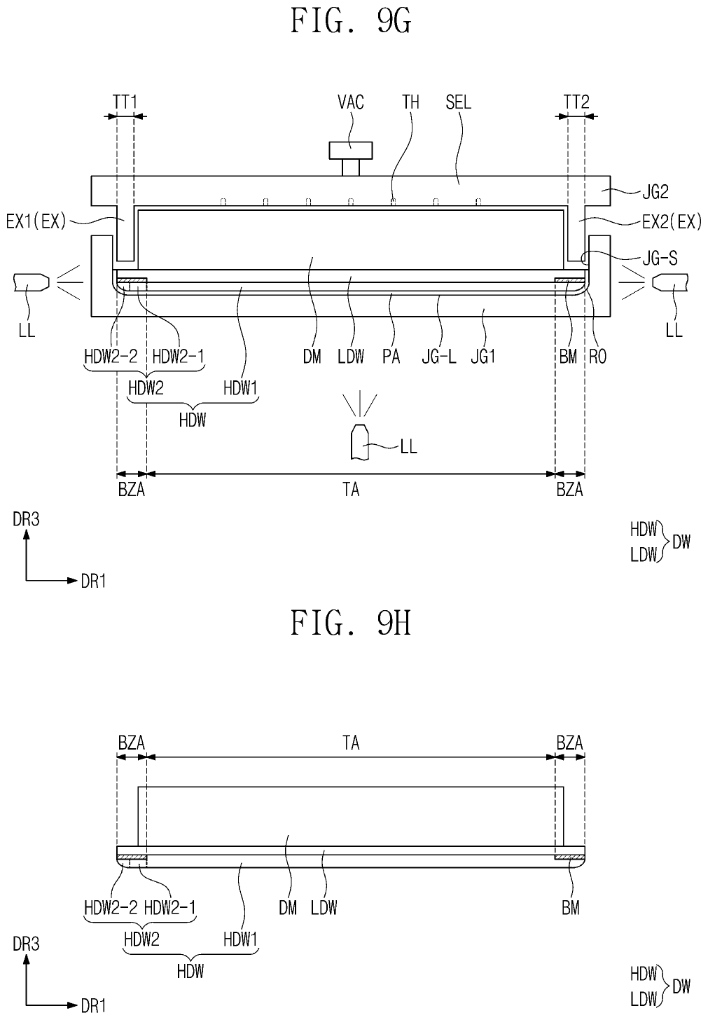

FIGS. 9A to 9H are sectional views illustrating a manufacturing method of the display device DD (refer to FIG. 5) according to an embodiment of the present disclosure.

Referring to FIG. 9A, the method may include providing a first resin material RE1 on a seating surface of a first jig JG1. The seating surface of the first jig JG1 may include an inner surface JG-S, a lower surface JG-L, and a curved surface RO of the first jig JG1. The curved surface RO of the first jig JG1 may be a curved surface formed between the inner surface JG-S and the lower surface JG-L of the first jig JG1.

The curved surface RO of the first jig JG1 may have a curvature corresponding to the curvature of the front surface FS2 of the portion HDW2-2 illustrated in FIG. 6. The method may include disposing a release coating layer PA on the inner surface JG-S, the lower surface JG-L, and the curved surface RO of the first jig JG1. The release coating layer PA may support a relatively easier separation (e.g., compared to without the release coating layer PA) of the window DW (refer to FIG. 9G) from the first jig JG1 in a subsequent process. The method may include coating a portion of the seating surface of the first jig JG1 that corresponds to the window DW in FIG. 9G with the release coating layer PA. The method may include applying the first resin material RE1 to the seating surface of the first jig JG1 coated with the release coating layer PA.

Referring to FIG. 9B, the method may include curing the applied first resin material RE1 (refer to FIG. 9A) by light generated from an exposure apparatus LL. The cured first resin material RE1 may form the second window HDW. The second window HDW may include the first portion HDW1 corresponding to the transmission region TA (refer to FIG. 9C) and the second portion HDW2 corresponding to the bezel region BZA (refer to FIG. 9C). The first portion HDW1 and the portion HDW2-1 may have a flat shape corresponding to the flat seating surface of the first jig JG1. In some embodiments, front surfaces and rear surfaces of the first portion HDW1 and the portion HDW2-1 may each have a flat shape.

The portion HDW2-2 may have a curved shape corresponding to the curved surface RO of the first jig JG1. The front surface of the portion HDW2-2 may include a portion curved toward the rear surface as the distance from the transmission region TA (refer to FIG. 9C) increases. Here, the front surface of the portion HDW2-2 may be a surface adjacent to the lower surface JG-L of the first jig JG1, and the rear surface of the portion HDW2-2 may be opposite the front surface of the portion HDW2-2 and be relatively further from (e.g., far away from) the lower surface JG-L of the first jig JG1.

Referring to FIGS. 9C and 9D, the method may include forming the light blocking pattern BM. In an embodiment, the light blocking pattern BM is directly disposed on the second window HDW and overlaps the bezel region BZA. Referring to FIG. 9C, the method may include applying a light blocking material BML to the portion HDW2-1 and the portion HDW2-2. Referring to FIG. 9D, the method may include curing the applied light blocking material BML (refer to FIG. 9C) by light generated from the exposure apparatus LL to form the light blocking pattern BM.

The exposure apparatus LL may be disposed adjacent to an outside surface of the first jig JG1, such that a distance between the exposure apparatus LL and the outside surface of the first jig JG1 supports sufficient curing of the light blocking pattern BM disposed adjacent to the inner surface JG-S of the first jig JG1. In this example case, for example, the first jig JG1 may include a material that passes or transmits UV light. For example, UV light may pass through the material. In an example, the first jig JG1 may include quartz. Accordingly, UV light generated from the exposure apparatus LL may pass through the first jig JG1 and may reach the light blocking pattern BM.

Referring to FIG. 9E, the method may include providing or disposing a second resin material RE2 on the first window LDW. The second resin material RE2 may cover the upper surface of the light blocking pattern BM.

Referring to FIG. 9F, the method may include disposing the display module DM on a second jig JG2. The second jig JG2 may include a support portion SEL on which the display module DM is seated and a protruding portion EX that protrudes from the support portion SEL. The protruding portion EX may include a first protruding portion EX1 and a second protruding portion EX2. In some embodiments, the width TT1 of the first protruding portion EX1 may be equal to the width TT2 of the second protruding portion EX2. In some embodiments, the first protruding portion EX1 and the second protruding portion EX2 may have the same height HH1. In an embodiment, the height HH1 of the first and second protruding portions EX1 and EX2 may be smaller than the thickness HH2 of the display module DM.

The method may include connecting the second jig JG2 with an attraction module VAC. A plurality of holes TH may be defined in the support portion SEL of the second jig JG2 that makes contact with the display module DM. The method may include generating an attraction force by the attraction module VAC and transmitting the attraction force to the display module DM through the plurality of holes TH. Accordingly, for example, the method may include fixing the display module DM to one surface of the second jig JG2 without the display module DM being dropped due to gravitational forces.

Referring to FIGS. 9F and 9G, the method may include moving the second jig JG having the display module DM disposed thereon in a direction opposite to the third direction DR3. The first jig JG1 may be movable in the third direction DR3. The second jig JG2 may have a shape corresponding to the first jig JG1. Accordingly, the method may include moving the second jig JG2 toward the first jig JG1.

The method may include directly disposing the display module DM on the second resin material RE2 by pressing the first jig JG1 and the second jig JG2. For example, the method may include pressing the first jig JG1 in a direction toward the second jig JG2 and/or pressing the second jig JG2 in a direction toward the first jig JG1. In an example, the second resin material RE2 is in an uncured state, and due to the uncured state, the second resin material RE2 may provide an adhesive force to the display module DM. The second resin material RE2 may include an additive for increasing the adhesive force. The additive may be an acrylate-based additive. However, the type of additive is not limited thereto, and any type of material capable of increasing an adhesive force may be used.

The exposure apparatus LL may provide light. In an example, the method may include providing light toward the second resin material RE2 and the display module DM, via the exposure apparatus LL, in the state in which the second resin material RE2 and the display module DM are in contact with each other. The method may include curing the second resin material RE2 by light generated from the exposure apparatus LL to form the first window LDW. The first jig JG1 and the second jig JG2 may include a material that passes UV light. Accordingly, for example, light generated from the exposure apparatus LL disposed outside the first jig JG1 and the second jig JG2 may reach the second resin material RE2 disposed inside the first jig JG1.

In some embodiments, the widths TT1 and TT2 of the respective protruding portions EX1 and EX2 may correspond to the distance between the outside surface of the display module DM and the outside surface of the second window HDW. The width TT1 of the first protruding portion EX1 may correspond to the distance between the left side surface of the display module DM and the left side surface of the second window HDW. In an example, the width of the first protruding portion EX1 may be smaller than the distance between the left side surface of the display module DM and the inner surface JG-S of the first jig JG1 that is adjacent to the left side surface of the display module DM.

The width TT2 of the second protruding portion EX2 may correspond to the distance between the right side surface of the display module DM and the right side surface of the second window HDW. In an example, the width TT2 of the second protruding portion EX2 may be smaller than the distance between the right side surface of the display module DM and the inner surface JG-S of the first jig JG1 that is adjacent to the right side surface of the display module DM.

In some embodiments, a minimum distance in the first direction DR1 between the first protruding portion EX1 and the second protruding portion EX2 may correspond to the width of the display module DM in the first direction DR1. In some embodiments, a minimum distance between the inner surface of the first protruding portion EX1 and the inner surface of the second protruding portion EX2 may correspond to the width of the display module DM in the first direction DR1.

The first protruding portion EX1 and the second protruding portion EX2 may guide the display module DM such that the display module DM is disposed at a specific position on the first window LDW. For example, respective structures of the first protruding portion EX1 and the second protruding portion EX2 may guide the display module DM. The first protruding portion EX1 and the second protruding portion EX2 may be inserted into depressions of the first jig JG1. In this example case, for example, the display module DM disposed between the first protruding portion EX1 and the second protruding portion EX2 may be disposed at a specific position on the window DW. The center of the display module DM and the center of the window DW may overlap each other on the plane.

The height HH1 of the first and second protruding portions EX1 and EX2 may be smaller than the thickness HH2 of the display module DM. Accordingly, for example, when the first jig JG1 and the second jig JG2 are pressed (e.g., in directions toward each other), distal ends of the first and second protruding portions EX1 and EX2 are not in contact with the second resin material RE2. That is, the distal ends of the first and second protruding portions EX1 and EX2 may be spaced apart from the upper surface of the second resin material RE2 or the upper surface of the first window LDW.

Referring to FIGS. 9G and 9H, the method may include removing the first and second jigs JG1 and JG2 from the window DW and the display module DM. In an example, the first jig JG1 is coated with the release coating layer PA, and the release coating layer PA may support relatively easier separation and removal (e.g., compared to without the release coating layer PA) of the first jig JG1 from the window DW. The method may include separating the second jig JG2 from the display module DM by removing the attraction force of the attraction module VAC.

In the case of using the manufacturing process of FIGS. 9A to 9H, the structure in which the outside surface of the window DW protrudes further outward compared to the outside surface of the display module DM may be formed even though the window DW is formed by applying and curing the resin materials.

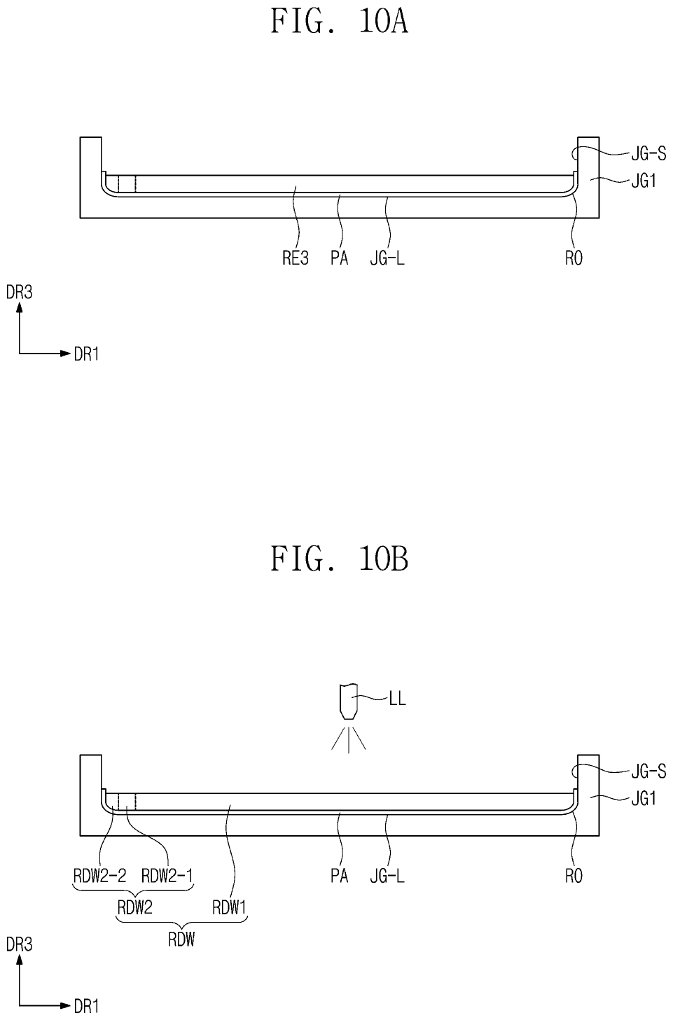

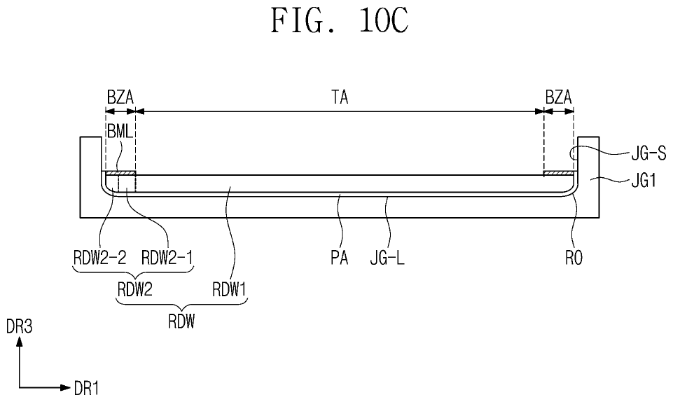

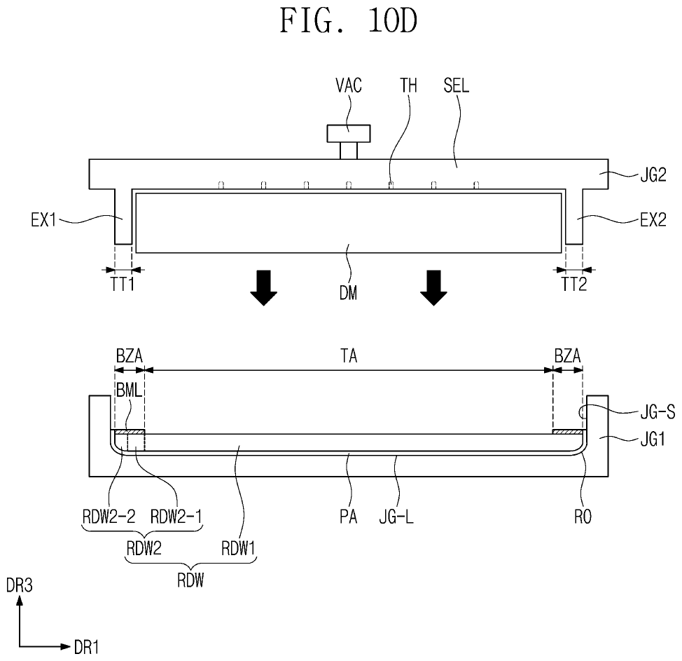

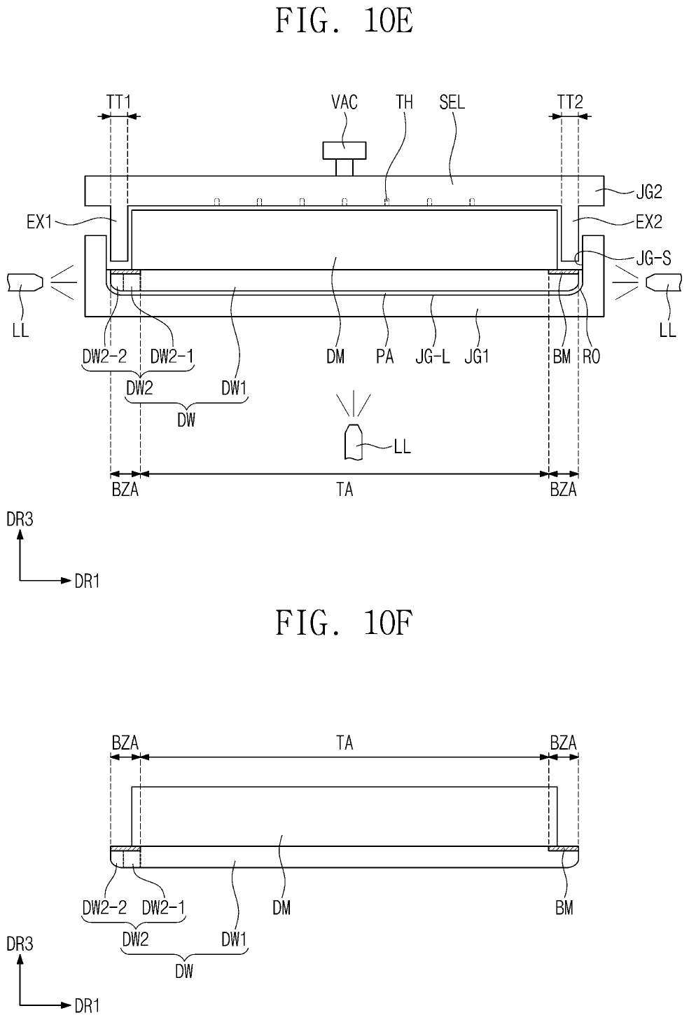

FIGS. 10A to 10F are sectional views illustrating a manufacturing method of the display device DD (refer to FIG. 7) according to an embodiment of the present disclosure. Components identical to the components described with reference to FIGS. 9A to 9H are assigned with identical reference identifiers, and repeated descriptions of like elements will be omitted for brevity.

Referring to FIG. 10A, the method may include providing a third resin material RE3 on the seating surface of the first jig JG1. That is, for example, the method may include applying the third resin material RE3 to the seating surface of the first jig JG1 coated with the release coating layer PA.

Referring to FIGS. 10A and 10B, the method may include temporarily curing the applied third resin material RE3 by light generated from the exposure apparatus LL. The temporarily cured third resin material RE3 may form a preliminary window RDW. Here, the temporary curing may mean curing the third resin material RE3 to such an extent that the light blocking material BML is able to be printed as in FIG. 10C without completely curing the third resin material RE3.

In some cases, if the third resin material RE3 is completely cured, the preliminary window RDW may fail to provide an adhesive force when the preliminary window RDW and the display module DM are brought into contact with each other as illustrated in FIG. 10E. Accordingly, the method may include curing the third resin material RE3 to such an extent that the light blocking material BML is able to be printed on the third resin material RE3. For example, the method may include adjusting the intensity of light generated from the exposure apparatus LL and the exposure time and include curing the third resin material RE3 based on the adjusted intensity of light and the adjusted exposure time.

The preliminary window RDW may include a first portion RDW1 corresponding to the transmission region TA (refer to FIG. 10C) and a second portion RDW2 corresponding to the bezel region BZA (refer to FIG. 10C). The first portion RDW1 and a portion RDW2-1 may have a flat shape corresponding to the flat seating surface of the first jig JG1.

A portion RDW2-2 may have a curved shape corresponding to the curved surface RO of the first jig JG1. The front surface of the portion RDW2-2 may include a portion curved toward the rear surface as the distance from the transmission region TA (refer to FIG. 10C) increases.

Referring to FIG. 10C, the method may include applying the light blocking material BML to the portion RDW2-1 and the portion RDW2-2 of the preliminary window RDW.

Referring to FIG. 10D, the method may include disposing the display module DM on the second jig JG2. The method may include moving the second jig JG2 having the display module DM disposed thereon in the direction opposite to the third direction DR3. The method may include moving the first jig JG1 in the third direction DR3. The second jig JG2 may have a shape corresponding to the first jig JG1.

Referring to FIGS. 10D and 10E, the method may include directly disposing the display module DM on the preliminary window RDW by pressing the first jig JG1 and the second jig JG2. For example, the method may include pressing the first jig JG1 in a direction toward the second jig JG2 and/or pressing the second jig JG2 in a direction toward the first jig JG1. The second jig JG2 may be inserted into the first jig JG1. When the first jig JG1 and the second jig JG2 are moved toward each other, the lower surface of the display module DM may make contact with the upper surface of the light blocking material BML before making contact with the upper surface of the preliminary window RDW. However, According to one or more embodiments of the present disclosure, the light blocking material BML has a thickness of 5 micrometers or less and is in an uncured state. Accordingly, for example, the method may include bringing the display module DM into contact with the upper surface of the preliminary window RDW by applying downward pressure to the display module DM.

The preliminary window RDW may provide an adhesive force to the display module DM because the preliminary window RDW is not completely cured. The preliminary window RDW may include an additive for increasing an adhesive force.

The method may include providing, by the exposure apparatus LL, light in the state in which the preliminary window RDW makes contact with the display module DM. The method may include completely curing the preliminary window RDW by light generated from the exposure apparatus LL to form the window DW. In some embodiments, the method may include curing the light blocking material BML together with the preliminary window RDW (e.g., at the same time as the curing of the preliminary window RDW) to form the light blocking pattern BM. The first jig JG1 and the second jig JG2 may include a material that passes UV light. Accordingly, for example, light generated from the exposure apparatus LL disposed outside the first jig JG1 and the second jig JG2 may reach the preliminary window RDW disposed inside the first jig JG1.

Referring to FIGS. 10E and 10F, the method may include removing the first and second jigs JG1 and JG2 from the window DW and the display module DM. In an example, the first jig JG1 is coated with the release coating layer PA, and the release coating layer PA may support relatively easier separation and removal (e.g., compared to without the release coating layer PA) of the first jig JG1 from the window DW. The method may include separating the second jig JG2 from the display module DM by removing the attraction force of the attraction module VAC.

In the display device according to the embodiments of the present disclosure, the light blocking pattern is disposed on the window, and the outside surface of the window protrudes further outward compared to the outside surface of the display module. Accordingly, the light blocking pattern may cover the non-display region of the display panel and the outside.

According to the embodiments of the present disclosure, the window may be formed using the first jig, and the display module may be fixed to the window through the second jig. Accordingly, the window directly disposed on the display module may be formed.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display module;
a window including a transmission region and a bezel region adjacent to the transmission region, the window being directly disposed on the display module and including a resin material; and
a light blocking pattern overlapping the bezel region,
wherein an outside surface of the window protrudes further outward compared to an outside surface of the display module, and
wherein a front surface of the window includes a curved portion, and the curved portion curves toward a rear surface of the window as a distance from the transmission region increases.

2. The display device of claim 1, wherein the window includes:
a first window directly disposed on the display module, the first window having a first modulus value; and
a second window directly disposed on the first window, the second window having a second modulus value greater than the first modulus value.

3. The display device of claim 2, wherein the light blocking pattern is directly disposed between the first window and the second window.

4. The display device of claim 1, wherein the window includes:
a first portion overlapping the transmission region, wherein a distance between a front surface and a rear surface of the first portion is constant; and
a second portion overlapping the bezel region, wherein a distance between a front surface and a rear surface of the second portion decreases as the distance from the first portion increases.

5. The display device of claim 1, wherein the light blocking pattern is directly disposed on the rear surface of the window.

6. The display device of claim 1, wherein the window is spaced apart from the outside surface of the display module.

7. The display device of claim 1, wherein the light blocking pattern has a thickness of 5 micrometers or less.

8. The display device of claim 1, wherein a width of the window in a first direction is greater than a width of the display module in the first direction.

9. A method for manufacturing a display device, the method comprising:
providing a first resin material on a first jig including a seating surface, wherein at least a portion of the seating surface between an inner surface and a lower surface of the seating surface is defined to be curved;
forming a first window by curing the first resin material, the first window including a transmission region and a bezel region adjacent to the transmission region;
forming a light blocking pattern directly disposed on the first window and overlapping the bezel region;
providing a second resin material on the first window;
directly placing a display module on the second resin material; and
forming a second window by curing the second resin material.

10. The method of claim 9, wherein the directly placing of the display module on the second resin material includes:
placing the display module on a second jig having a shape corresponding to the first jig; and
directly placing the display module on the second resin material by pressing the first jig and the second jig by moving at least one of the first jig and the second jig.

11. The method of claim 10, wherein the second jig is coupled with an attraction module and attracts the display module based on an attraction force generated by the attraction module, and
wherein the second jig fixes the display module to one surface of the second jig based on the attraction force generated by the attraction module.

12. The method of claim 10, wherein the second jig includes a support portion on which the display module is seated and a protruding portion protruding from the support portion, and
wherein a width of the protruding portion corresponds to a distance between an outside surface of the display module and an outside surface of the second window.

13. The method of claim 12, wherein a height of the protruding portion is smaller than a thickness of the display module.

14. The method of claim 10, wherein at least one of the first jig and the second jig includes a material which transmits UV light.

15. The method of claim 9, wherein a front surface of the first window includes a curved portion, and the curved portion curves toward a rear surface as a distance from the transmission region increases, and
wherein the seating surface of the first jig substantially corresponds to the curved portion.

16. A method for manufacturing a display device, the method comprising:
providing a resin material on a first jig including a seating surface, wherein at least a portion of the seating surface between an inner surface and a lower surface of the seating surface is defined to be curved;
forming a preliminary window by pre-curing the resin material, the preliminary window including a transmission region and a bezel region adjacent to the transmission region;
forming a light blocking pattern directly disposed on the preliminary window and overlapping the bezel region;
directly placing a display module on the preliminary window; and
forming a window by curing the preliminary window.

17. The method of claim 16, wherein the directly placing of the display module on the preliminary window includes:
placing the display module on a second jig having a shape corresponding to the first jig; and
directly placing the display module on the preliminary window by pressing the first jig and the second jig by moving at least one of the first jig and the second jig.

18. The method of claim 17, wherein the second jig includes a protruding portion protruding toward the first jig, and
wherein a thickness of the protruding portion in a first direction corresponds to a distance between an outside surface of the display module and an outside surface of the window.

19. The method of claim 17, wherein at least one of the first jig and the second jig includes a material which transmits UV light.

20. The method of claim 16, wherein a front surface of the window includes a curved portion, and the curved portion curves toward a rear surface as a distance from the transmission region increases, and
wherein the seating surface of the first jig substantially corresponds to the curved portion.
